(19) United States
(12) Patent Application Publication
(10) Pub. No.: US 2011/0285447 A1
(43) Pub. Date: Nov. 24, 2011

(54) DRIVE CIRCUIT

(75) Inventor: Ryouta NAKANISHI, Niiza-shi (JP)

(73) Assignee: Sanken Electric Co., Ltd., Niiza-shi (JP)

(21) Appl. No.: 13/106,219

(22) Filed: May 12, 2011

(30) Foreign Application Priority Data
May 19, 2010 (JP) 2010-115200

(51) Int. Cl. H03K 5/08

(52) U.S. Cl. 327/326

(57) ABSTRACT

A drive circuit includes a transformer T1 having a primary winding N1 to which a drive signal P1 is applied and a first secondary winding N2, a first switching element Q1, a first capacitor C3 connected between a first end of the first secondary winding of the transformer and a control terminal of the first switching element, and a first series circuit including a first zener diode ZN1 and a second zener diode ZN2, a cathode of the first zener diode being connected to a connection point of the first capacitor and first switching element, a cathode of the second zener diode being connected to a second end of the first secondary winding.

### BACKGROUND OF THE INVENTION

1. Field of the Invention

The present invention relates to a drive circuit that uses a transformer to drive a switching element.

2. Description of Related Art

FIG. 1 is a circuit diagram illustrating a drive circuit according to a related art. In FIG. 1, a pulse generator P1 generates a pulse signal, which is supplied through a resistor R1 and a capacitor C1 to a primary winding N1 of a transformer T1. Then, a secondary winding N2 of the transformer T1 generates a pulse signal, which is applied through a resistor R2 to a switching element Q1 that is a MOSFET, thereby turning on/off the switching element Q1.

If the secondary winding N2 is directly connected to the switching element Q1 and if the pulse signal from the secondary winding N2 has an ON-duty ratio of 50%, the maximum value of the pulse signal exceeds a threshold value Vth of the switching element Q1, to turn on the switching element Q1. If the ON-duty ratio of the pulse signal from the secondary winding N2 increases far from 50%, the maximum value of the pulse signal decreases in proportion to a pulse width. If the maximum value decreases below the threshold value Vth of the switching element Q1, the switching element Q1 will not turn on. In this way, the related art of FIG. 1 causes a fluctuation in a drive voltage for the switching element Q1 if the ON-duty ratio of the pulse signal from the secondary winding N2 varies.

To solve this problem, Japanese Unexamined Patent Application Publication No. 2001-345194 (Patent Document 1) discloses a drive circuit illustrated in FIG. 2. Operating waveforms of this drive circuit are illustrated in FIG. 3. When the ON-duty ratio of a drive signal Vs from a controller 112 increases, the related art increases a voltage Vc13, which is supplied from a DC power source Vcc through FETs Q11 and Q12 to a primary winding nN1 of a transformer T11. As the voltage Vc13 increases, a voltage VT2 of a secondary winding nN2 of the transformer T11 increases. Namely, a maximum value of the voltage VT2 of the secondary winding nN2 is maintained at a constant value to easily drive a switching element Q.

### SUMMARY OF THE INVENTION

The drive circuit of the related art illustrated in FIG. 2, however, must detect the ON-duty ratio and increase the first driving source voltage Vcc (Vc13) to increase the second driving source voltage VT2. Namely, the related art must have two driving source voltages, thereby increasing the number of power source parts and cost.

The present invention provides a drive circuit that is realized with a reduced number of power source parts and at low cost.

According to an aspect of the present invention, the drive circuit includes a transformer having a primary winding to which a drive signal is applied and at least one secondarywinding including a first secondary winding, a first switching element configured to be turned on/off in response to a signal outputted from the first secondary winding of the transformer, a first capacitor connected between a first end of the first secondary winding of the transformer and a control terminal of the first switching element, and a first series circuit including a first zener diode and a second zener diode, a cathode of the first zener diode being connected to a connection point of the first capacitor and first switching element, a cathode of the second zener diode being connected to a second end of the first secondary winding.

According to another aspect of the present invention, a first diode is connected to both end of the first capacitor in parallel with the first capacitor.

### BRIEF DESCRIPTION OF THE DRAWINGS

FIG. 1 is a circuit diagram illustrating a drive circuit according to a related art;

FIG. 2 is a circuit diagram illustrating a drive circuit according to another related art;

FIG. 3 is a waveform diagram illustrating operating waveforms of the drive circuit of FIG. 2;

FIG. 4 is a circuit diagram illustrating a drive circuit according to Embodiment 1 of the present invention;

FIG. 5 is a graph illustrating an operating waveform of the drive circuit according to Embodiment 1;

FIG. 6 is a circuit diagram illustrating a current loop of the drive circuit according to Embodiment 1 when a secondary winding voltage is negative;

FIG. 7 is a circuit diagram illustrating voltages at various parts of the drive circuit according to Embodiment 1 when the secondary winding voltage is positive;

FIG. 8 is a circuit diagram illustrating the drive circuit of Embodiment 1 with a flyback transformer;

FIG. 9 is a graph illustrating a gate-source voltage Vgs of a switching element Q1 at starting of the drive circuit of FIG. 8;

FIG. 10 is a graph illustrating voltage waveforms of a secondary winding N2 and capacitor C3 at starting of the drive circuit of FIG. 8;

FIG. 11 is a graph illustrating a secondary winding voltage after charging the capacitor C3 of the drive circuit of FIG. 8;

FIG. 12 is a circuit diagram illustrating a drive circuit according to Embodiment 2 of the present invention;

FIGS. 13A and 13B are graphs illustrating operating waveforms of the drive circuit according to Embodiment 2;

FIG. 14 is a circuit diagram illustrating a drive circuit according to Embodiment 3 of the present invention;

FIGS. 15A, 15B, and 15C are graphs illustrating operating waveforms of the drive circuit according to Embodiment 3 without a diode D1;

FIGS. 16A, 16B, and 16C are graphs illustrating operating waveforms of the drive circuit according to Embodiment 3 with the diode D1;

FIG. 17 is a circuit diagram illustrating a drive circuit according to Embodiment 4 of the present invention;

FIGS. 18A, 18B, and 18C are graphs illustrating operating waveforms of the drive circuit according to Embodiment 4; and

FIG. 19 is a circuit diagram illustrating a drive circuit according to Embodiment 5 of the present invention.

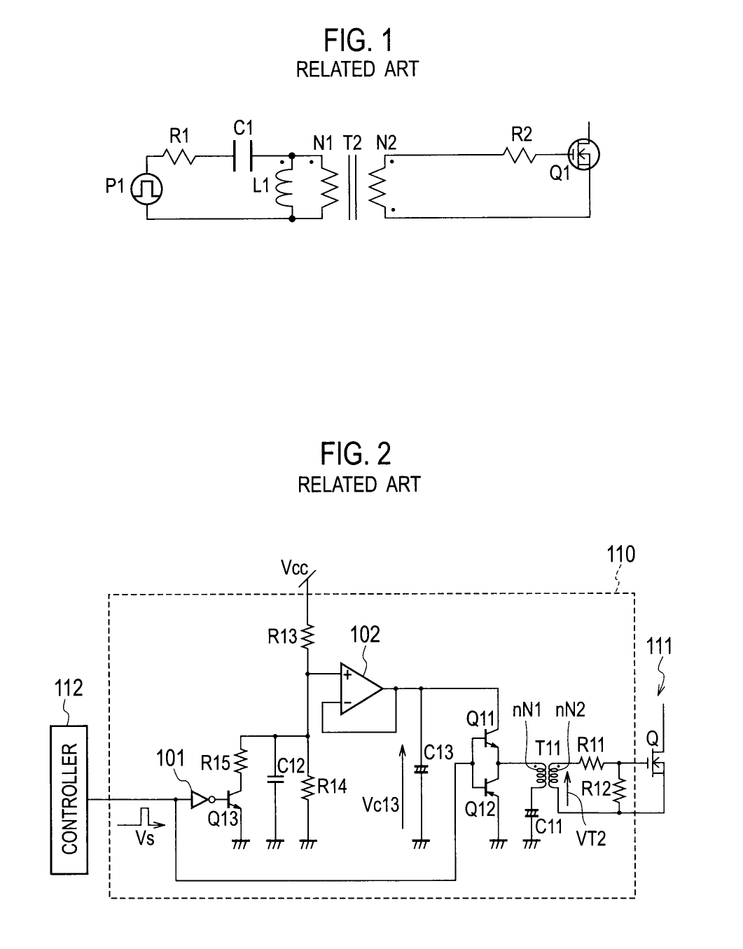

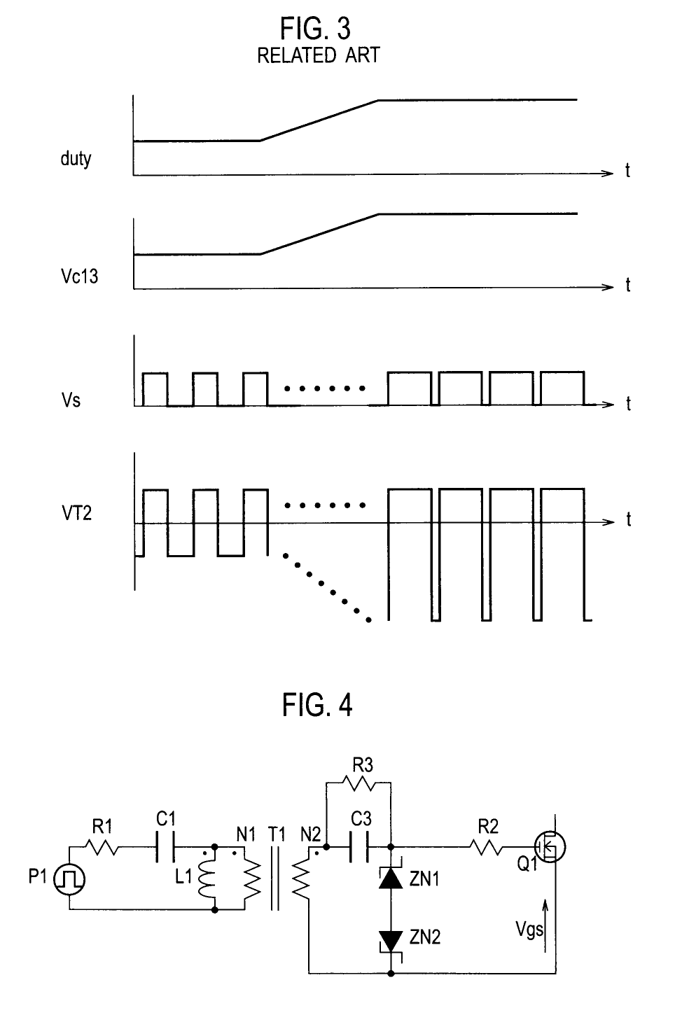

### DESCRIPTION OF PREFERRED EMBODIMENTS

The embodiments of the present invention will be explained in detail with reference to the drawings.

### Embodiment 1

FIG. 4 is a circuit diagram illustrating a drive circuit according to Embodiment 1 of the present invention. In FIG. 4, both ends of a pulse generator P1 are connected to a series circuit including a resistor R1, a capacitor C1, and a primary winding N1 of a transformer T1. The primary winding N1 has an exciting inductance L1. The primary winding N1 and a secondary winding N2 (corresponding to the first secondary winding stipulated in the claims) of the transformer T1 are wound inphase.

A first end of the secondary winding N2 of the transformer T1 is connected to a first end of a parallel circuit including a resistor R3 and a capacitor C3. A second end of the parallel circuit is connected to a cathode of a zener diode ZN1 (corresponding to the first zener diode stipulated in the claims) and a first end of a resistor R2. A second end of the resistor R2 is connected to a gate (control terminal) of a switching element Q1 (corresponding to the first switching element stipulated in the claims) made of, for example, a MOSFET.

The resistor R3 is a discharge resistor to discharge the capacitor C3 after a power source of the drive circuit is turned off. The resistor R3 may be omitted.

An anode of the zener diode ZN1 is connected to an anode of a zener diode ZN2 (corresponding to the second zener diode stipulated in the claims). A cathode of the zener diode ZN2 is connected to a second end of the secondary winding N2 and a source of the switching element Q1.

The pulse generator P1 generates a pulse signal (corresponding to the drive signal stipulated in the claims), which is applied through the resistor R1 and capacitor C1 to the primary winding N1 of the transformer T1. In proportion to a turn ratio with respect to the primary winding N1, the secondary winding N2 generates a voltage Vn2.

When the voltage Vn2 of the secondary winding N2 is negative, the voltage Vn2 makes the zener diode ZN2 conductive to cause a current passing counterclockwise through a path extending along N2, ZN2, ZN1, C3, and N2 as illustrated in FIG. 6, thereby charging the capacitor C3. At this time, the capacitor C3 has a charge voltage Vc3 of (Vn2−Vzn2).

Here, a forward voltage Vf of the zener diode ZN1 is ignored. The negative voltage of the secondary winding N2 is clamped by the zener diode ZN2, so that the negative voltage has a constant voltage waveform.

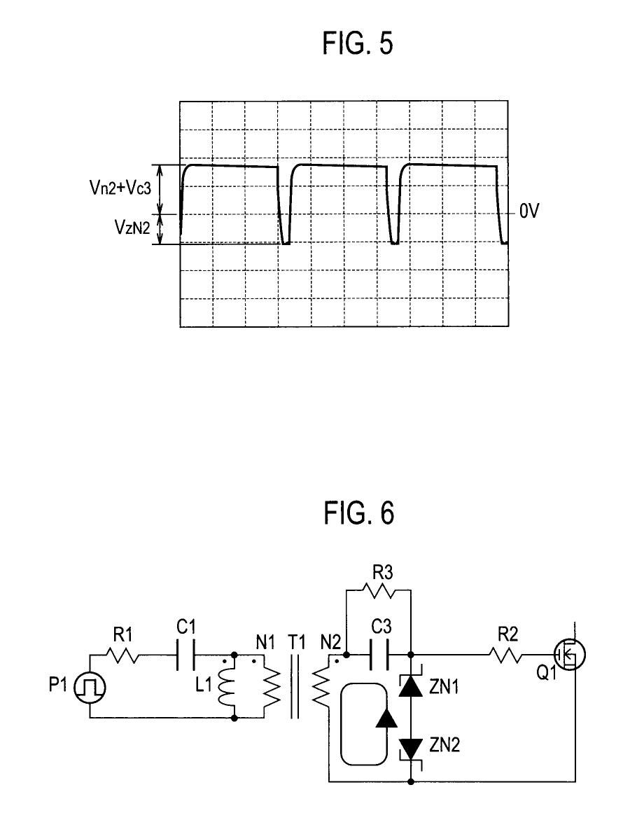

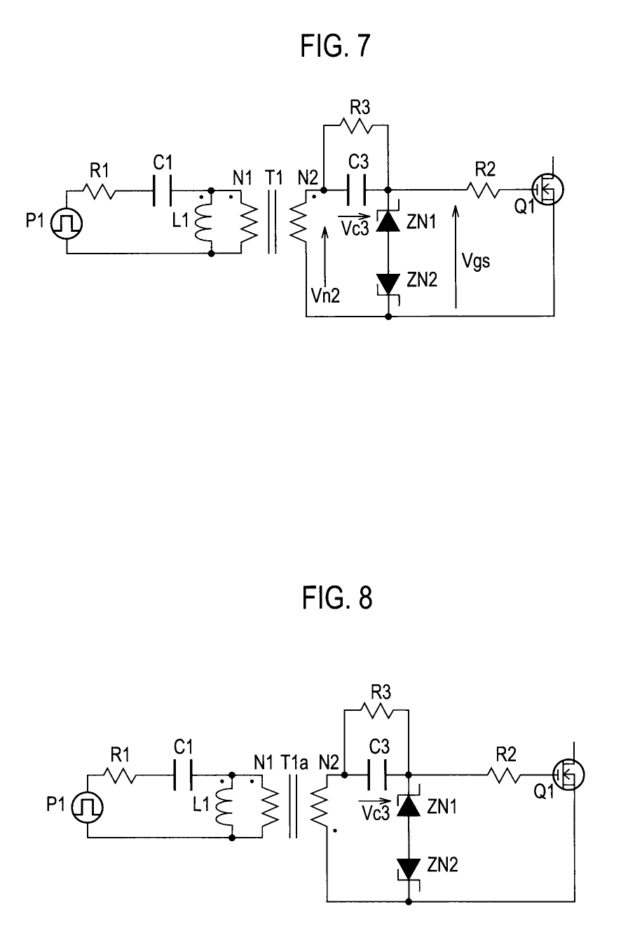

When the voltage Vn2 of the secondary winding N2 is positive, the voltage Vc3 of the capacitor C3 is superimposed on the positive voltage Vn2 as illustrated in FIG. 7. As a result, a gate-source drive voltage Vgs to the switching element Q1 reaches a level of (Vn2+Vc3) that is a maximum voltage as illustrated in FIG. 5.

A breakdown voltage of the zener diode ZN2 is set so that, when the pulse signal from the pulse generator P1 has a maximum ON-duty ratio, the voltage of (Vn2+Vc3) exceeds a threshold value Vth of the switching element Q1 to properly drive the switching element Q1.

In this way, the drive circuit according to the present embodiment uses a single driving source voltage to properly drive the switching element Q1 even when the ON-duty ratio of the pulse signal from the pulse generator P1 is at the maximum. The drive circuit according to Embodiment 1, therefore, reduces the number of power source parts and cost.

### Embodiment 2

Before explaining a drive circuit according to Embodiment 2 of the present invention, a problem that may occur if the transformer of the drive circuit according to Embodiment 1 is a flyback transformer will be explained with reference to FIG. 8. Compared with the transformer T1 of Embodiment 1 illustrated in FIG. 4, the flyback transformer T1a of FIG. 8 has a primary winding N1 and a secondary winding N2 that are wound in reverse phase. Namely, in FIG. 8, a start point (depicted by a dot) of the primary winding N1 is opposite to a start point (depicted by a dot) of the secondary winding N2.

If the drive circuit of FIG. 8 is started with a pulse signal of a large ON-duty ratio applied to the primary side of the transformer T1a, an ON-duty ratio on the secondary side of the transformer T1a becomes small because the pulse signal is inverted on the secondary side. At this time, the voltage Vn2 of the secondary winding N2 and the voltage Vc3 of the capacitor C3 are as illustrated in FIG. 10.

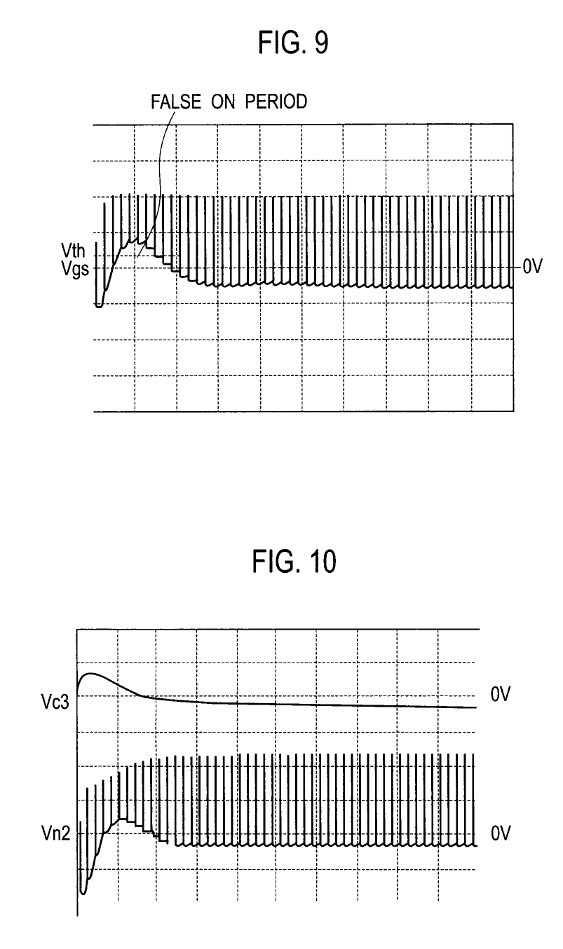

A drive voltage to the switching element Q1, i.e., the gate-source voltage Vgs is (Vn2+Vc3), and as illustrated in FIG. 9, there is a period in which the DC component is superimposed on the drive voltage. If the DC-component-superimposed voltage exceeds the threshold value Vth of the switching element Q1, the switching element Q1 will continuously be ON during a period of the voltage Vgs being above the threshold value Vth. Namely, as illustrated in FIG. 9, there will be a false ON period in which the switching element Q1 is erroneously ON because the voltage Vgs is above the threshold value Vth.

At initial stage of operation of the drive circuit, the voltage of the capacitor C1 is zero, and therefore, a pulse voltage applied to the primary side of the transformer T1a is substantially applied to the primary winding N1. As a result, the secondary winding N2 of the transformer T1a generates a large negative voltage to make the zener diode ZN2 conductive to charge the capacitor C3 in the direction of an arrow (Vc3) as illustrated in FIG. 8.

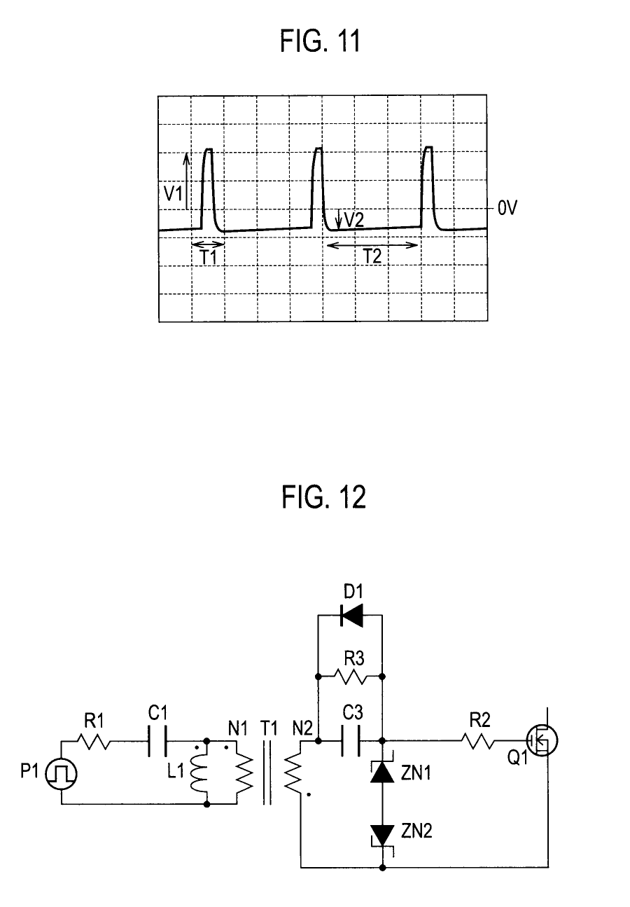

As the capacitor C3 is charged, the voltage of the primary winding N1 alternates between positive and negative sides, and on the secondary winding N2, a product of (V1 (positive voltage)×T1 (time)) is equalized with a product of (V2 (negative voltage)×T2 (time)) as illustrated in FIG. 11. At this time, the ON-duty ratio of the secondary winding N2 is small, and therefore, a positive peak voltage increases to make the zener diode ZN1 conductive. Then, the capacitor C3 is charged in a direction opposite to the direction illustrated in FIG. 8, to demonstrate the waveforms illustrated in FIGS. 9 and 10 involving the false ON period.

To solve the problem of the false ON period of the switching element Q1 that may occur with the flyback transformer T1a, the drive circuit according to the present embodiment employs a configuration illustrated in FIG. 12. In FIG. 12, the drive circuit of the present embodiment additionally connects a diode D1 in parallel with the parallel circuit of the capacitor C3 and resistor R3 of the drive circuit of Embodiment 1 illustrated in FIG. 4. A cathode of the diode D1 is connected to the first end of the secondary winding N2 and an anode of the diode D1 is connected to the cathode of the zener diode ZN1.

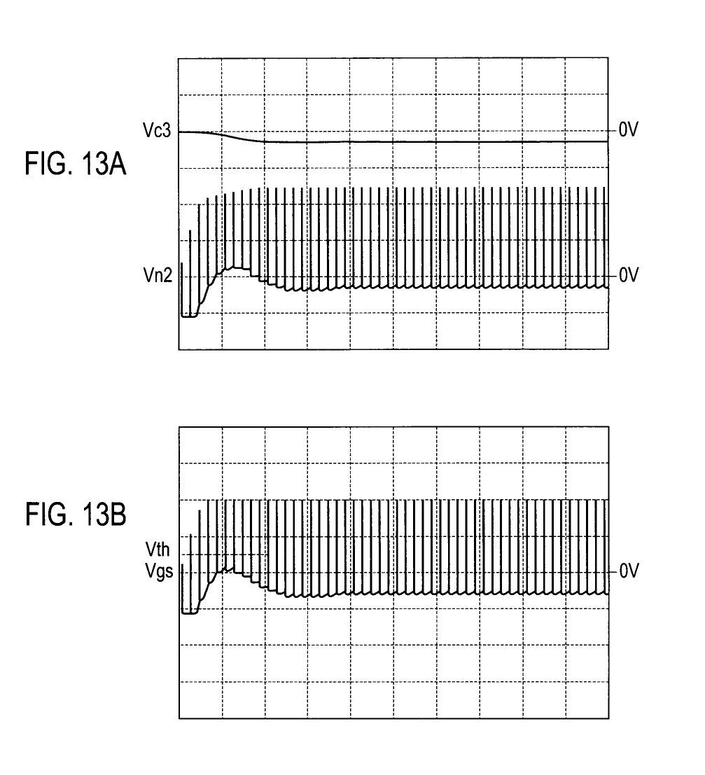

When the secondary winding N2 of the transformer T1 provides a negative voltage at initial state of operaton of the drive circuit of the present embodiment, a current passes counterclockwise through a path extending along N2, ZN2, ZN1, D1, and N2, so that the capacitor C3 is substantially not charged. Accordingly, as illustrated in FIG. 13A, the voltage Vc3 of the capacitor C3 at the start is clamped by a forward voltage Vf of the diode D1, and therefore, decreases. At this time, the voltage Vn2 of the secondary winding N2 is clamped by the zener diode ZN2, and therefore, becomes a negative constant voltage at the start as illustrated in FIG. 13A.

As a result, the gate-source voltage Vgs to the switching element Q1, i.e., the voltage of (Vn2+Vc3) decreases so that the voltage of an envelope that is tangent to lower limit values of pulses becomes smaller than the threshold value Vth of the switching element Q1, thereby preventing the occurrence of the false ON period. Namely, according to Embodiment 2, the switching element Q1 is never continuously ON at starting of the drive circuit.

### Embodiment 3

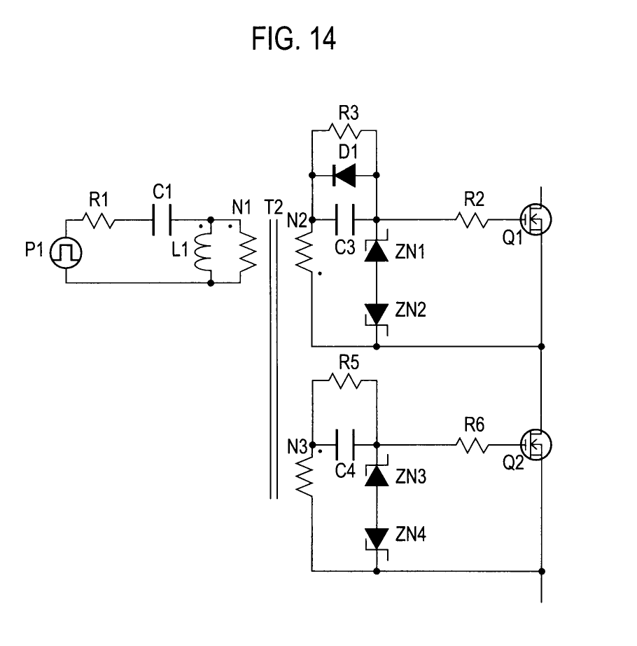

FIG. 14 is a circuit diagram illustrating a drive circuit according to Embodiment 3 of the present invention. In FIG. 14, the drive circuit drives a low-side switching element Q2 and a high-side switching element Q1 that are connected in series. To drive these switching elements Q1 and Q2, the drive circuit includes a transformer T2, a secondary circuit for the switching element Q1, and a secondary circuit for the switching element Q2.

The transformer T2 has a primary winding N1, a first secondary winding N2, and a second secondary winding N3. The first secondary winding N2 is in reverse phase with respect to the primary winding N1. Connected between ends of the first secondary winding N2 are a parallel circuit including a capacitor C3, a resistor R3, and a diode D1 and a series circuit including zener diodes ZN1 and ZN2. The series circuit of the zener diodes ZN1 and ZN2 is connected to a resistor R2 and the gate and source of the switching element Q1.

Connected between ends of the second secondary winding N3 are a parallel circuit including a capacitor C4 and a resistor R5 and a series circuit including zener diodes ZN3 and ZN4. The series circuit of the zener diodes ZN3 and ZN4 is connected to a resistor R6 and the gate and source of the switching element Q2.

The resistors R3 and R5 are discharge resistors configured to discharge the capacitors C3 and C4 after a power source of the drive circuit is turned off and may be omitted.

A turn ratio between the primary and secondary windings of the transformer T2 is optionally determined so that a power source voltage of the drive circuit on the primary side may sufficiently drive gate voltages to the switching elements Q1 and Q2. The high side has an ON-duty ratio of below 50%.

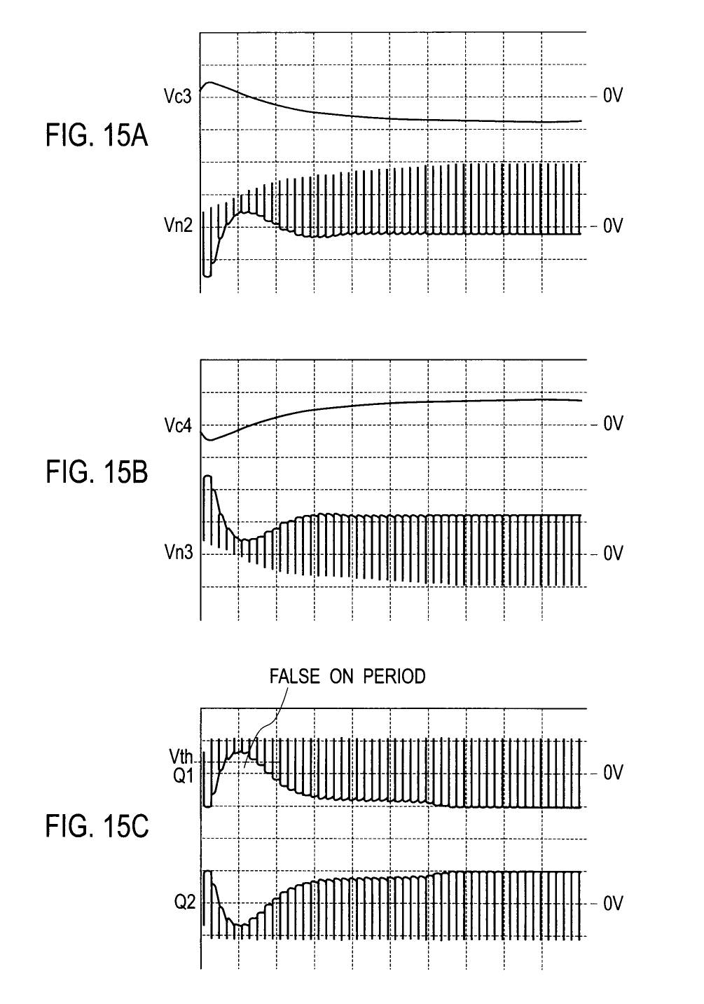

FIGS. 15A, 15B, and 15C are graphs illustrating operating waveforms of the drive circuit according to Embodiment 3 if no diode D1 is provided. FIG. 15A illustrates waveforms of a voltage Vc3 of the high-side capacitor C3 and a voltage Vn2 of the first secondary winding N2, FIG. 15B illustrates waveforms of a voltage Vc4 of the low-side capacitor C4 and a voltage Vn3 of the second secondary winding N3, and FIG. 15C illustrates gate waveforms of the switching elements Q1 and Q2.

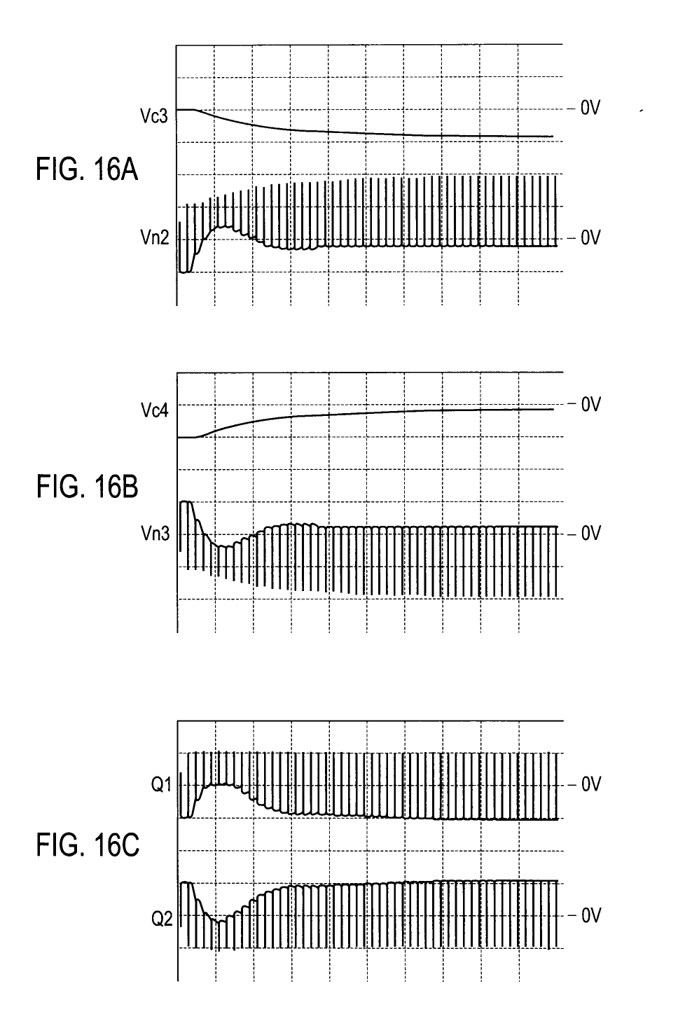

FIGS. 16A, 16B, and 16C are graphs illustrating operating waveforms of the drive circuit according to Embodiment 3 with the diode D1. FIG. 16A illustrates waveforms of the high-side voltages Vc3 and Vn2, FIG. 16B illustrates waveforms of the low-side voltages Vc4 and Vn3, and FIG. 16C illustrates gate waveforms of the switching elements Q1 and Q2.

Like the drive circuit of Embodiment 2, the drive circuit of Embodiment 3 makes the diode D1 conductive at starting of the drive circuit, so that the diode D1 clamps the charge voltage of the capacitor C3, to prevent the DC component from being superimposed. As illustrated in FIG. 16A, the high-side voltages Vc3 and Vn2 after the start decrease to prevent an occurrence of the false ON period of the switching element Q1.

The first and second secondary windings N2 and N3 are electromagnetically coupled with each other, and therefore, the low-side voltages Vc4 and Vn3 are influenced by the high-side voltages Vc3 and Vn2. Accordingly, the diode D1 prevents superposition of the DC component and lowers the low-side voltages Vc4 and Vn3 after the start as illustrated in FIG. 16B.

### Embodiment 4

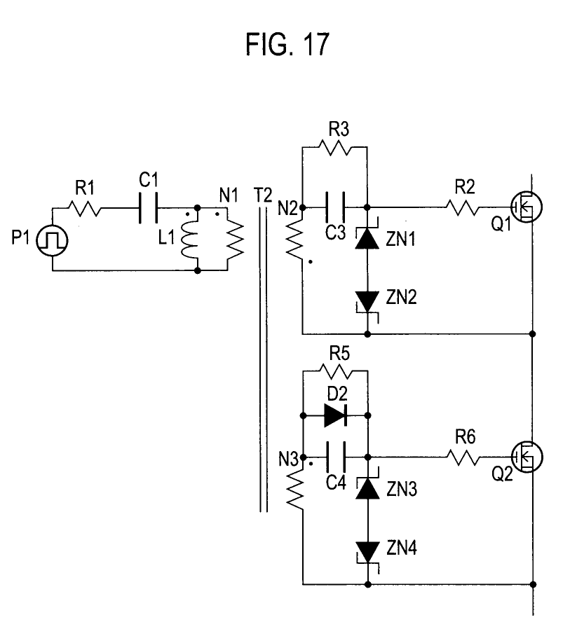

FIG. 17 is a circuit diagram illustrating a drive circuit according to Embodiment 4 of the present invention. Unlike the drive circuit of Embodiment 3 illustrated in FIG. 14 that connects the diode D1 in parallel with the high-side capacitor C3, the drive circuit of Embodiment 4 illustrated in FIG. 17 connects a diode D2 in parallel with a low-side capacitor C4.

A second secondary winding N3 of a transformer T2 is wound in reverse phase with respect to a first secondary winding N2 of the transformer T2. A first end of the second secondary winding N3 is connected to an anode of the diode D2. A cathode of the diode D2 is connected to a cathode of a zener diode ZN3.

The present embodiment sets a breakdown voltage of the zener diode ZN3 to a sufficiently low value so that, when the diode D2 becomes conductive at starting of the drive circuit, a voltage Vn3 of the second secondary winding N3 is applied to the zener diode ZN3, to make the zener diode ZN3 conductive.

When the zener diode ZN3 becomes conductive, the voltage Vn3 of the second secondary winding N3 becomes equal to the voltage of the zener diode ZN3. At this time, a voltage Vn2 of the first secondary winding N2 has a value determined by a turn ratio between the first and second secondary windings N2 and N3. For example, a turn ratio among a primary winding N1 having the number of turns of n1, the first secondary winding N2 having the number of turns of n2, and the second secondary winding N3 having the number of turns of n3 is set to 1:1:1.

When the zener diode ZN3 becomes conductive, the voltage Vn3 of the second secondary winding N3, the voltage Vzn3 of the zener diode ZN3, and the voltage Vn2 of the first secondary winding N2 become equal to one another.

A zener diode ZN2 is so selected that a breakdown voltage of the zener diode ZN2 is equal to or larger than that of the zener diode ZN3, so that the zener diode ZN2 does not become conductive at starting of the drive circuit, and therefore, a capacitor C3 is not charged.

Like the drive circuit of Embodiment 3 that clamps the capacitor C3 by the diode D1, the drive circuit of Embodiment 4 prevents the DC superposition and the false ON period of a switching element Q1.

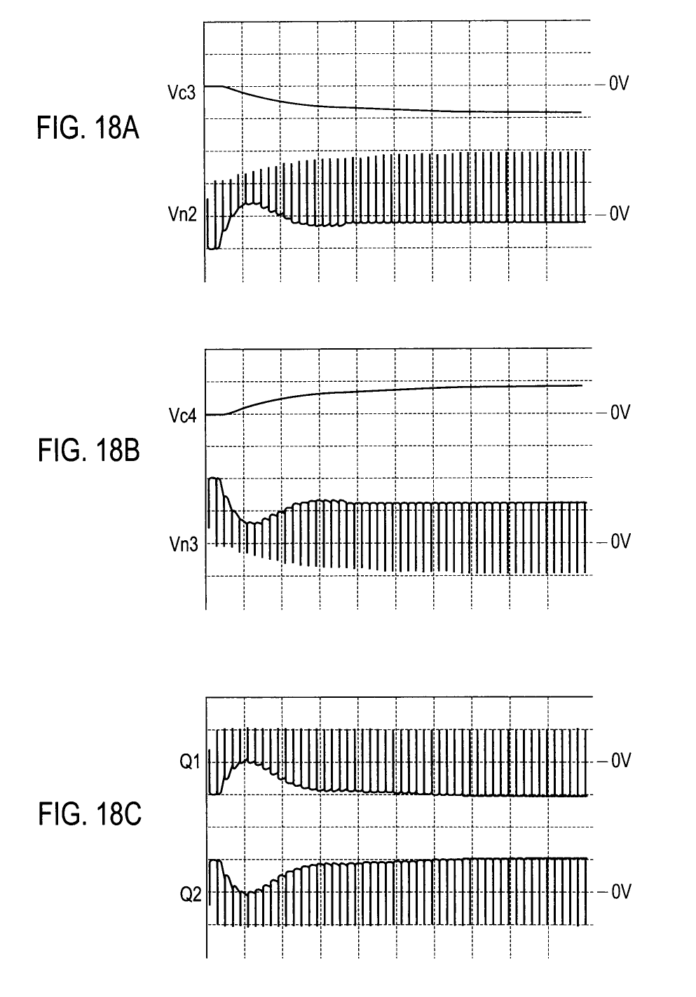

FIGS. 18A, 18B, and 18C are graphs illustrating operating waveforms of the drive circuit according to the present embodiment, in which FIG. 18A illustrates waveforms of high-side voltages Vc3 and Vn2, FIG. 18B illustrates waveforms of low-side voltages Vc4 and Vn3, and FIG. 18C illustrates gate waveforms to the switching elements Q1 and Q2. As illustrated in FIG. 180, Embodiment 4 prevents an occurrence of the false ON period of the switching element Q1.

### Embodiment 5

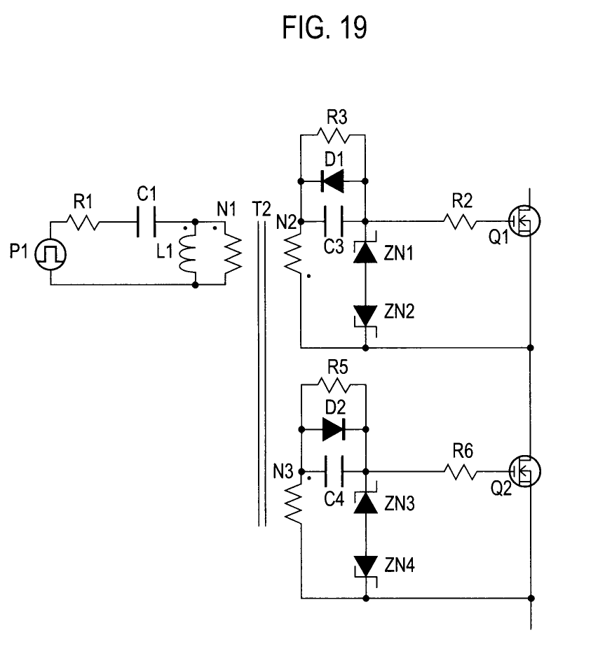

FIG. 19 is a circuit diagram illustrating a drive circuit according to Embodiment 5 of the present invention. In FIG. 19, a diode D1 is connected in parallel with a high-side capacitor C3 and a diode D2 is connected in parallel with a low-side capacitor C4. The drive circuit of Embodiment 5 illustrated in FIG. 19 is a combination of the drive circuit of Embodiment 3 illustrated in FIG. 14 and the drive circuit of Embodiment 4 illustrated in FIG. 17. Accordingly, the drive circuit of Embodiment 5 operates like the drive circuits of Embodiments 3 and 4 and provides like effect.

The present invention is not limited to the drive circuits of Embodiments 1 to 5 mentioned above. For example, the primary winding N1 and secondary windings may oppositely be wound in Embodiment 3 of FIG. 14, Embodiment 4 of FIG. 17, and Embodiment 5 of FIG. 19. In this case, the diodes D1 and D2 are reversely oriented.

In this way, the drive circuit according to the present invention drives a switching element with a single driving source voltage, thereby reducing the number of power source parts and cost. When the voltage of the first secondary winding N2 is negative at starting of the drive circuit, the first diode ZN1 passes a current so that the first capacitor C3 is substantially not charged. Namely, the voltage of the first capacitor C3 is clamped by a forward voltage of the first diode ZN1. This results in reducing a voltage applied to the first switching element Q1 at starting of the drive circuit, thereby preventing the first switching element Q1 from having a false ON period.

The present invention is widely applicable to power source apparatuses.

This application claims benefit of priority under 35USC §119 to Japanese Patent Application No. 2010-115200, filed on May 19, 2010, the entire contents of which are incorporated by reference herein. Although the invention has been described above by reference to certain embodiments of the invention, the invention is not limited to the embodiments described above. Modifications and variations of the embodiments described above will occur to those skilled in the art, in light of the teachings. The scope of the invention is defined with reference to the following claims.

What is claimed is:

1. A drive circuit comprising:
a transformer (T1) having a primary winding (N1) to which a drive signal (P1) is applied and at least one secondary winding including a first secondary winding (N2);
a first switching element (Q1) configured to be turned on/off in response to a signal outputted from the first secondary winding of the transformer;
a first capacitor (C3) connected between a first end of the first secondary winding of the transformer and a control terminal of the first switching element; and
a first series circuit including a first zener diode (ZN1) and a second zener diode (ZN2), a cathode of the first zener diode being connected to a connection point of the first capacitor and first switching element, and a cathode of the second zener diode being connected to a second end of the first secondary winding.

2. The drive circuit according to claim 1, further comprising
a first diode connected to both end of the first capacitor in parallel with the first capacitor.

3. The drive circuit according to claim 2, further comprising:
a second secondary winding (N3) provided for the transformer;
a second switching element (Q2) connected in series with the first switching element;
a second capacitor (C4) connected between a first end of the second secondary winding of the transformer and a control terminal of the second switching element; and
a second series circuit including a third zener diode (ZN3) and a fourth zener diode (ZN4), a cathode of the third zener diode being connected to a connection point of the second capacitor and second switching element, a cathode of the fourth zener diode being connected to a second end of the second secondary winding of the transformer.

4. The drive circuit of claim 3, further comprising
a second diode (D2) connected to both ends of the second capacitor in parallel with the second capacitor.
